(19) United States
(12) Patent Application Publication
(10) Pub. No.: US 2008/0296053 A1
(43) Pub. Date: Dec. 4, 2008

(54) ELECTRONIC COMPONENT MODULE AND METHOD OF MANUFACTURING THE SAME

(75) Inventors: Yukihiro Ishimaru, Osaka (JP); Toshiyuki Kojima, Osaka (JP); Rikiya Okimoto, Osaka (JP)

Correspondence Address: RATNERPRESTIA, P.O. BOX 980, VALLEY FORGE, PA, 19482, US

(73) Assignee: Matsushita Electric Industrial Co., Ltd., Osaka (JP)

(21) Appl. No.: 12/127,279

(22) Filed: May 27, 2008

(30) Foreign Application Priority Data
May 28, 2007 (JP) 2007-141172

(51) Int. Cl. H05K 1/16; H05K 3/30

(52) U.S. Cl. 174/260; 29/832

(57) ABSTRACT

A method of manufacturing an electronic component module includes mounting an electronic component on at least one surface of a first board, subsequently inspecting the first board for functions, forming a resin layer burying or covering the electronic component on the one surface of the first board to flatten the one surface side of the first board, aligningly stacking the first board, a plate-like member and a second board so that the other surface of the first board is opposite one surface of the plate-like member and so that the other surface of the plate-like member is opposite one surface of the second board, pressurizing the first board, the plate-like member and the second board which have been stacked, and heating the first board, the plate-like member, and the second board which have been stacked.

### BACKGROUND OF THE INVENTION

1. Field of the Invention

The present invention relates to an electronic component module and a method of manufacturing the electronic component module.

2. Related art of the Invention

With the reduced size and thickness and improved functions of electronics instruments in recent years, there has been a growing demand to more densely mount electronic components on a printed circuit board and to improve the functions of the circuit board with the electronic components mounted thereon. In this situation, component-equipped boards having electronic components buried in the board have been developed (see, for example, Japanese Patent Laid-Open No. 2003-197849).

In the component-equipped board, active components (for example, semiconductor elements) and passive components (for example, capacitors) otherwise mounted on a surface of a printed circuit board are buried in the board. Thus, the area of the board can be reduced. Compared to surface mounting, this technique improves the flexibility for arranging electronics components, allowing wires among the electronic components to be optimized. Consequently, frequency characteristics can also be expected to be improved.

In the field of ceramic boards, LTCC (Low Temperature Cofired Ceramics) boards with built-in electronic components have been put to practical use. However, the LTCC boards with the built-in electronic components are heavy and easy to break and are thus difficult to apply to large-sized boards. Furthermore, these boards require thermal treatments at high temperatures and are thus seriously limited; semiconductor elements such as LSIs cannot be built into the board. Much attention has recently been paid to component-equipped boards having components built into a printed circuit board using resin. Unlike the LTCC boards, these boards advantageously do not suffer a serious limitation on the size of the board and can contain LSIs.

Now, the component-equipped board (component-equipped module) disclosed in Japanese Patent Laid-Open No. 2003-197849 will be described with reference to FIGS. 15(A) to 15(C). FIGS. 15(A) to 15(C) are sectional views of the configuration of a conventional component-equipped module illustrating a method of manufacturing the module. FIG. 15(C) is a sectional view showing the configuration of a circuit component-equipped module 700 manufactured.

The circuit component-equipped module 700 shown in FIG. 15(C) comprises an electric insulating layer 701 and wiring boards 708 each provided over or under the electric insulating layer 701. A wiring pattern 702 is formed on each of the wiring boards 708. Vias 703 are formed in the electric insulating layer 701 to electrically connect the upper and lower wiring boards 708. Electronic components 704 and 706 are built in the vias 703. The electronic component 706 is a semiconductor. The electronic components 704 and 706, built in the electric insulating layer 701, are mounted on the wiring board 708 located over or under the electric insulating layer 701. Moreover, the electronic components 704 and 706 are mounted on a top surface of the wiring board 708 located over the electric insulating layer 701. The electronic components 704 and 706 are also mounted on a bottom surface of the wiring board 708 located under the electric insulating layer 701.

Now, with reference to FIGS. 15(A) and 15(B), description will be given of a method of manufacturing a component-equipped board disclosed in Japanese Patent Laid-Open No. 2003-197849.

A plate-like member 720 is formed by processing a mixture containing an inorganic filler and a thermosetting resin. Subsequently, the vias 703 are formed in the plate-like member 720. Spaces 710 are formed in areas of the plate-like member 720 into which the built-in components are to be inserted. Through-holes that are used to form the vias 703 can be formed by, for example, laser processing, drilling, or processing with a mold. A conductive resin composition is subsequently filled into the through-holes.

On the other hand, as shown in FIG. 15(A), the electronic components 704 and 706 are mounted on a bottom surface of the upper wiring board 708 by flip-chip bonding. The electronic components 704 and 706 are mounted on a top surface of the lower wiring board 708 by flip-chip bonding. The electronic components and semiconductor elements are electrically connected to the wiring boards 708 via a conductive adhesive.

And then checks to confirm the mounting condition whether mounting the electronic components and semiconductor elements on the upper and lower wiring boards 708 is correctly processed or not is performed.

Then, as shown in FIG. 15(B), the two wiring boards 708 and the plate-like member 720 are aligningly stacked. The aligningly stacked boards and plate-like member are pressurized to form a plate-like unit with the electronic components buried therein. The plate-like unit is then heated to cure the thermosetting resin in the mixture and conductive resin composition to form the electric insulating layer 701 with the electronic components 704 and 706 buried therein.

Subsequently, the electronic components 704 and 706 are arranged on each of a top surface of the upper wiring board 708 and a bottom surface of the lower wiring board 708 to form the circuit component-equipped module 700.

As described above, with the conventional manufacturing method, the mounting condition is inspected with the electronic components arranged on only one surface of the wiring board 708 (see FIG. 15(A)). However, since present electronics instruments use a large number of components to provide complicated functions, a module circuit may not be completed until the electronic components are mounted on both surfaces of the circuit board. Thus, the inspections other than visual inspections of solder connections or the like may be difficult unless function inspections are performed on the circuit completed by mounting the electronic components on both surfaces of the board (see FIG. 15(C)).

When the board with the electronic components mounted on both surfaces thereof as shown in FIG. 15(C) is inspected to detect any inappropriate component or connection, if that component is built in the component-equipped module, then the component is difficult to repair. Furthermore, even if any defect is detected through function inspections, the cause of the defect needs to be determined in order to repair and improve the component. However, since about half of the components constituting the circuit in the component-equipped module are arranged inside the board, the components cannot be brought into direct contact with a probe or the like. Consequently, the defective portion is difficult to locate.

On the other hand, when the wiring board 708 and the plate-like member 720 are aligningly pressurized, a press machine that sandwiches the components between rigid bodies is commonly used. The pressurization is thus difficult unless the relevant surface is flat.

That is, it is difficult to mount the electronic components 704 and 706 on both surfaces of the wiring board 708 and then aligningly pressurize the wiring board 708 and the plate-like member 720, in order to allow the board to be inspected for functions.

In FIG. 15(C), the electronic components are built in the electric insulating layer. However, even with a module with no electronic component built therein, if electronic components are located on a side of the module against which a mold of the press machine abuts, the electronic components cannot be arranged before the pressurization. Thus, even when any defect is found through function inspections after the module has been completed, repairs or the like may be difficult.

### SUMMARY OF THE INVENTION

In view of the problems with the conventional electronic component-equipped module, an object of the present invention is to provide an electronic component module that allows the board to be more precisely inspected before pressurization, as well as a method of manufacturing the electronic component module.

The 1^{st} aspect of the present invention is a method of manufacturing an electronic component module, the method comprising:

forming a plate-like member containing an uncured thermosetting resin;

mounting one or more electronic components on at least one surface of a first board;

forming an abutting portion burying or covering the electronic components on the one surface of the first board to flatten the one surface side;

inspecting the first board after (a) the mounting one or more electronic components on at least one surface of a first board or (b) the forming an abutting portion burying or covering the electronic components on the one surface of the first board to flatten the one surface side;

aligningly stacking the first board, the plate-like member, and a second board so that the other surface of the first board on which the abutting portion is not formed is opposite one surface of the plate-like member and so that the other surface of the plate-like member is opposite one surface of the second board;

pressurizing the first board, the plate-like member, and the second board which have been stacked; and

heating the first board, the plate-like member, and the second board which have been stacked.

The 2^{nd} aspect of the present invention is the method of manufacturing the electronic component module according to the 1^{st} aspect of the present invention, wherein the mounting one or more electronic components on at least one surface of a first board means mounting an electronic component on the other surface as well as the one surface of the first board.

The 3^{rd} aspect of the present invention is the method of manufacturing the electronic component module according to the 1^{st} aspect of the present invention, further comprising:

forming a through-hole in the plate-like member; and

filling a thermosetting conductive material into the through-hole.

The 4^{th} aspect of the present invention is the method of manufacturing the electronic component module according to the 1^{st} aspect of the present invention, wherein the mounting one or more electronic components on at least one surface of a first board means mounting one or more electronic components on at least the other surface of the second board, the other surface of the second board being positioned opposite the plate-like member, and the forming an abutting portion burying or covering the electronic components on the one surface of the first board to flatten the one surface side means forming an abutting portion burying or covering the electronic components on the one surface of the second board to perform flattening.

The 5^{th} aspect of the present invention is the method of manufacturing the electronic component module according to the 1^{st} aspect of the present invention, wherein the mounting one or more electronic components on at least one surface of a first board means also mounting one or more electronic components on the one surface of the second board which is opposite the other surface of the plate-like member.

The 6^{th} aspect of the present invention is the method of manufacturing the electronic component module according to the 1^{st} aspect of the present invention, wherein the forming an abutting portion burying or covering the electronic components on the one surface of the first board to flatten the one surface side means forming the abutting portion by coating resin on the surface.

The 7^{th} aspect of the present invention is the method of manufacturing the electronic component module according to the 1^{st} aspect of the present invention, further comprising;

placing a metal foil on the flattened surface.

The 8^{th} aspect of the present invention is a method of manufacturing an electronic component module, the method comprising:

forming a plate-like member containing an uncured thermosetting resin;

mounting one or more electronic components on at least one surface of a first board;

forming an abutting portion on a part of the one surface of the first board in which the electronic components are not formed, the abutting portion having a height that is uniform and equal to or greater than that of a highest one of the electronic components on the one surface of the first board;

inspecting the first board after (a) the mounting one or more electronic components on at least one surface of a first board or (b) the forming an abutting portion on a part of the one surface of the first board in which the electronic components are not formed, the abutting portion having a height that is uniform and equal to or greater than that of a highest one of the electronic components on the one surface of the first board;

aligningly stacking the first board, the plate-like member, and a second board so that the other surface of the first board on which the abutting portion is not formed is opposite one surface of the plate-like member and so that the other surface of the plate-like member is opposite one surface of the second board;

pressurizing the first board, the plate-like member, and the second board which have been stacked; and

heating the first board, the plate-like member, and the second board which have been stacked.

The 9^{th} aspect of the present invention is the method of manufacturing the electronic component module according to the 8^{th} aspect of the present invention, wherein the mounting one or more electronic components on at least one surface of a first board means mounting an electronic component on the other surface as well as the one surface of the first board.

The 10^{th} aspect of the present invention is the method of manufacturing the electronic component module according to the 8^{th} aspect of the present invention, further comprising:

forming a through-hole in the plate-like member; and

filling a thermosetting conductive material into the through-hole.

The 11^{th} aspect of the present invention is the method of manufacturing the electronic component module according to the 8^{th} aspect of the present invention, wherein the forming an abutting portion on a part of the one surface of the first board in which the electronic components are not formed, the abutting portion having a height that is uniform and equal to or greater than that of a highest one of the electronic components on the one surface of the first board means forming the abutting portion by coating resin on the surface.

The 12^{th} aspect of the present invention is the method of manufacturing the electronic component module according to the 8^{th} aspect of the present invention, wherein the abutting portion has a plurality of abutting parts, and

forming the abutting portion on the part of the surface in which the electronic components are not formed means forming a plurality of the abutting parts of the same height on the surface around peripheries of the electronic components.

The 13^{th} aspect of the present invention is an electronic component module comprising:

a plate-like member;

a first board provided on one surface of the plate-like member and having a surface located opposite the plate-like member at least on which one or more electronic components are mouneted;

a second board provided on a surface of the plate-like member, the surface of the plate-like member being positioned opposite the first board; and

an abutting portion burying or covering the electronic components on the surface of the first board to flatten the surface side.

The 14^{th} aspect of the present invention is an electronic component module comprising:

a plate-like member;

a first board provided on one surface of the plate-like member and having a surface located opposite the plate-like member at least on which one or more electronic components are mounted;

a second board provided on a surface of the plate-like member, the surface of the plate-like member being positioned opposite the first board; and

an abutting portion formed on a part of the surface of the first board in which the electronic components are not formed, the abutting portion having a height that is uniform and equal to or greater than that of a highest one of the electronic components on the surface of the first board.

The present invention can provide an electronic component module that allows the boards to be more precisely inspected before pressurization, as well as a method of manufacturing the electronic component module.

### BRIEF DESCRIPTION OF THE DRAWINGS

FIG. 1 is a sectional view of an electronic component-equipped module according to Embodiment 1 of the present invention;

FIGS. 2(A) to 2(H) are sectional views illustrating a method of manufacturing the electronic component-equipped module according to Embodiment 1 of the present invention;

FIGS. 3(A) and 3(B) are sectional views illustrating an inspection jig for use in the method of manufacturing the electronic component-equipped module according to Embodiment 1 of the present invention;

FIG. 4 is a sectional view illustrating the method of manufacturing the electronic component-equipped module according to Embodiment 1 of the present invention;

FIGS. 5(A) to 5(H) are sectional views illustrating a method of manufacturing an electronic component-equipped module according to Embodiment 2 of the present invention;

FIG. 6 is a sectional view of an electronic component-equipped module according to Embodiment 2 of the present invention;

FIG. 7 is a sectional view of a variation of the electronic component-equipped module according to Embodiment 2 of the present invention;

FIG. 8 is a sectional view of a variation of the electronic component-equipped module according to Embodiment 2 of the present invention;

FIGS. 9(A) to 9(D) are sectional views illustrating a variation of the method of manufacturing the electronic component-equipped module according to Embodiment 2 of the present invention;

FIGS. 10(A) and 10(B) are sectional views illustrating a variation of the method of manufacturing the electronic component-equipped module according to Embodiment 2 of the present invention;

FIGS. 11(A) to 11(C) are sectional views illustrating a variation of the method of manufacturing the electronic component-equipped module according to Embodiment 2 of the present invention;

FIGS. 12(A) to 12(D) are sectional views illustrating a variation of the electronic component-equipped modules according to Embodiments 1 and 2 of the present invention;

FIG. 13(A) is an enlarged sectional view of the electronic component-equipped module according to Embodiment 1 of the present invention, FIG. 13(B) is a sectional view illustrating a variation of the electronic component-equipped modules according to Embodiments 1 and 2 of the present invention, FIG. 13(C) is a sectional view illustrating a variation of the electronic component-equipped modules according to Embodiments 1 and 2 of the present invention, and FIG. 13(D) is a sectional view illustrating a variation of the electronic component-equipped modules according to Embodiments 1 and 2 of the present invention;

FIGS. 14(A) to 14(C) are sectional views illustrating a variation of the methods of manufacturing the electronic component-equipped modules according to Embodiments 1 and 2 of the present invention; and

FIGS. 15(A) to 15(C) are sectional views illustrating a method of manufacturing a conventional electronic component-equipped module.

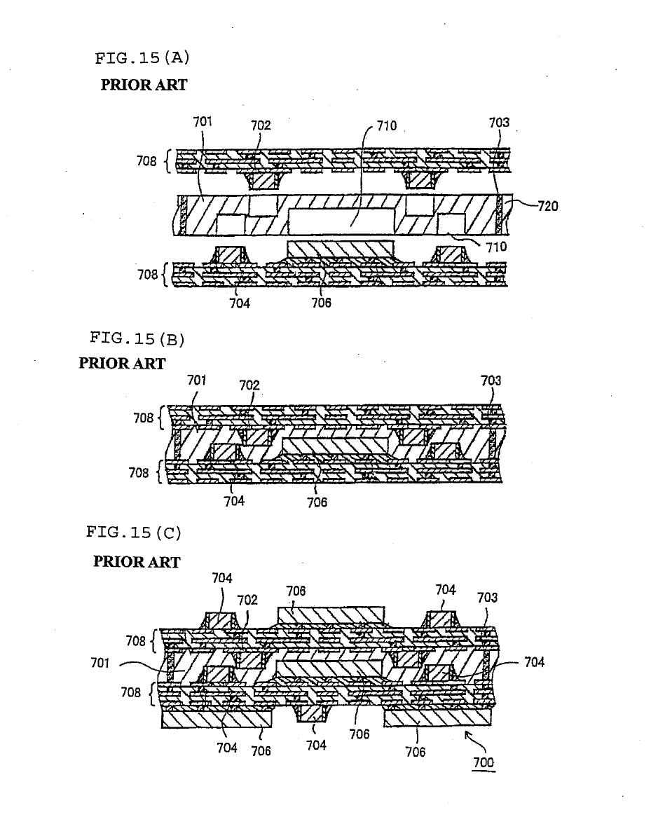

### DESCRIPTION OF SYMBOLS

1 Electronic component-equipped module
2 Electric insulating board
3 First board
3a Wiring pattern
4 Second board
4a Wiring pattern
5 Inner via
11, 12, 13, 14, 15, 16, 17 Electronic components
16 Resin layer
20 Plate-like member
21 Through-hole
22 Conductive resin composition
50 Copper foil

### PREFERRED EMBODIMENTS OF THE INVENTION

Embodiments of the present invention will be described below with reference to the drawings. In the drawings, for simplification of description, components having substantially the same functions are denoted by the same reference numerals.

### Embodiment 1

First, description will be given of the configuration of an electronic component-equipped module 1 as an example of an electronic component-equipped module according to the present invention.

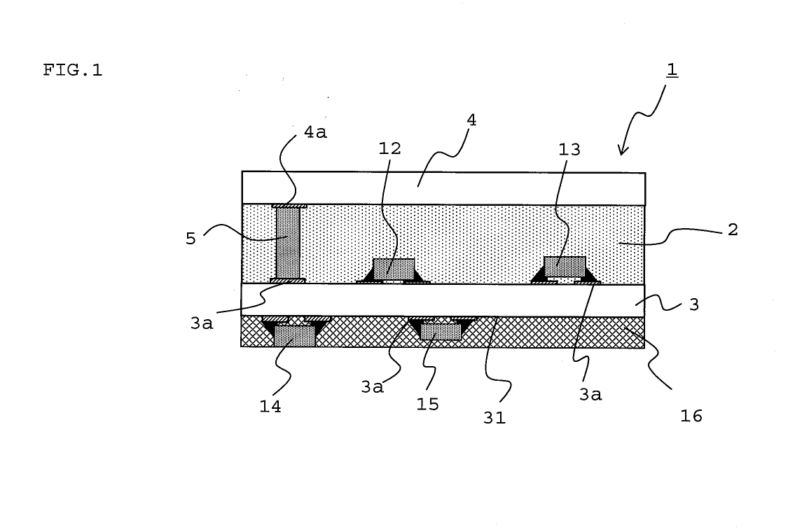

FIG. 1 is a sectional view of the configuration of an electronic component-equipped module 1 according to Embodiment 1. As shown in FIG. 1, the electronic component-equipped module 1 according to Embodiment 1 comprises an electric insulating board 2 formed of a mixture containing an inorganic filler and a thermosetting resin, a first board 3 provided on a bottom surface of the electric insulating board 2, and a second board 4 provided on a top surface of the electric insulating board 2.

Wiring patterns 3a and 4a are formed on the first board 3 and the second board 4, respectively. FIG. 1 shows only the main wiring patterns. To electrically connect the wiring pattern 3a on the first board 3, located on the bottom surface of the electric insulating board 2, to the wiring pattern 4a on the second board 4, located on the top surface of the electric insulating board 2, the built-in layer 2 has an inner via 5 formed therein. The inner via 5 is composed of a through-hole in which a conductive resin composition is filled.

The first board 3 has electronic components 12 and 13 mounted on a surface 30 thereof which is in contact with the electric insulating board 2, and electronic components 14 and 15 mounted on a surface 31 thereof which is opposite the electric insulating board 2 across the first board 3. The electronic components 12, 13, 14, and 15 are mounted on the first board 3 as flip-chips.

A resin layer 16 is formed on the surface 31 of the first board 3 so as to bury the electronic components 14 and 15. The resin layer 16 has the same height as that of the electronic component 14, and flattens the surface 31 side. Since the electronic component 14 is higher than the electronic component 15, the electronic component 15 is completely covered with resin.

The electronic component 14 is an example of a buried electronic component according to the present invention. The electronic component 15 is an example of a covered electronic component according to the present invention.

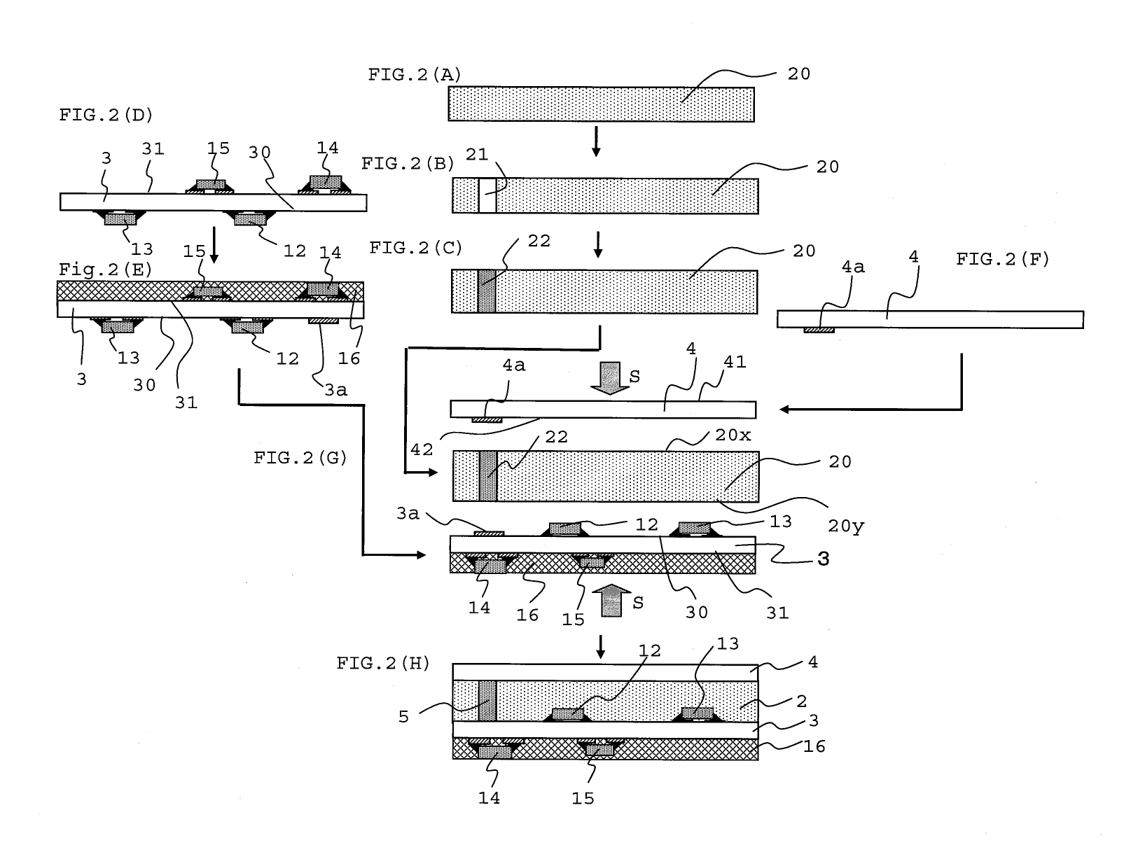

Now, description will be given of a method of manufacturing the electronic component-equipped module according to Embodiment 1, and an example of the method of manufacturing the electronic component-equipped module according to the present invention. FIGS. 2(A) to 2(H) are sectional views illustrating the method of manufacturing the electronic component-equipped module according to the present embodiment.

First, description will be given of the organization of a material (see FIG. 2(A)) for the electric insulating board 2 in the electronic component-equipped module according to Embodiment 1.

The material forming the electric insulating board 2 used in Embodiment 1 is the mixture of the inorganic filler and the thermosetting resin. Examples of the material are shown with sample numbers 1 to 13 in (Table 1). (Table 1) shows the composition of a mixture with each sample number. For example, the mixture with sample number 1 uses 60 wt % of Al₂O₃ as an inorganic filler, 39.8 wt % of liquid epoxy resin as a thermosetting resin, and 0.2 wt % of carbon black.

TABLE 1

| | | | | | | | Coefficient | | Dielectric | |
|---|---|---|---|---|---|---|---|---|---|---|
| | Inorganic filler | | Thermosetting resin | | Other | Heat | of linear | Dielectric | loss | Withstand |
| Sample | | Quantity | | Quantity | additives | conductivity | expansion | constant | 1 MHZ | voltage (AC) |
| number | Type | (wt %) | Type | (wt %) | (wt %) | (W/mK) | (ppm/° C.) | 1 MHZ | (%) | KV/mm |
| 1 | Al₂ O₃ | 60 | Liquid epoxy | 39.8 | Carbon black | 0.52 | 45 | 3.5 | 0.3 | 8.1 |
| 2 | Al₂O₃ | 70 | resin WE-2025 | 29.8 | (0.2) | 0.87 | 32 | 4.7 | 0.3 | 10.1 |
| 3 | Al₂O₃ | 80 | | 19.8 | | 1.2 | 26 | 5.8 | 0.3 | 16.5 |
| 4 | Al₂O₃ | 85 | | 14.8 | | 2.8 | 21 | 6.1 | 0.2 | 15.5 |
| 5 | Al₂O₃ | 90 | | 9.8 | | 4.5 | 16 | 6.7 | 0.2 | 18.7 |
| 6 | Al₂O₃ | 95 | | 4.8 | | 5.5 | 11 | 7.1 | 0.2 | 17.1 |
| 7 | MgO | 78 | | 21.8 | | 4.2 | 24 | 8.1 | 0.4 | 15.2 |
| 8 | BN | 77 | | 22.8 | Carbon black | 5.5 | 10 | 6.8 | 0.3 | 17.4 |
| 9 | AlN | 85 | | 14.8 | (0.2) | 5.8 | 18 | 7.3 | 0.3 | 19.3 |
| 10 | SiO₂ | 75 | | 24.8 | | 2.2 | 7 | 3.5 | 0.2 | 18.2 |
| 11 | Al₂O₃ | 90 | Phenol resin | 9.8 | Carbon black | 4.1 | 31 | 7.7 | 0.5 | 13.2 |
| 12 | Al₂O₃ | 90 | Cyanate resin | 9.8 | Dispersant | 3.8 | 15 | 6.7 | 0.2 | 14.5 |
| | | | | | (0.2) | | | | | |
| 13 | SiO₂ | 85 | Liquid epoxy | 14.5 | Coupling | 2.3 | 6 | 5.0 | 0.2 | 19.0 |
| | | | resin WE-2025 | | agent (0.5) | | | | | |

Liquid epoxy resin: manufactured by PELNOX, LTD; WE-2025
Phenol resin: manufactured by DAINIPPON INK AND CHEMICALS, INCORPORATED; Phenolite, VH-4150
Cyanate resin: manufactured by Asahi Ciba Corporation; AroCyM-30
Carbon black: manufactured by Toyo Tanso Co., Ltd.; R- 930
Dispersant: manufactured by DAI- ICHI KOGYO SBYAKU CO., LTD.; PLYSURF 5- 208F
Al₂O₃: manufactured by SHOWA DENKO K. K.; SA-40
SiO₂: manufactured by KANTO CHEMICAL CO., INC.; first- grade reagent
AlN: manufactured by The Dow Chemical Company
BN: manufactured by DENKI KAGAKU KOGYO KABUSHIKI KAISHA
MgO: manufactured by KANTO CHEMICAL CO., INC.; first-grade reagent

The liquid epoxy resin shown in (Table 1) is manufactured by PELNOX, LTD (WE-2025; containing an acid anhydride-containing curing agent). The phenol resin is manufactured by DAINIPPON INK AND CHEMICALS, INCORPORATED (Phenolite, VH4150). The cyanate resin is manufactured by Asahi Ciba Corporation (AroCy, M-30). Furthermore, in Embodiment 1, the carbon black or dispersant shown in (Table 1) is used as an additive.

The content of the inorganic filler allows heat generated from the electronic components to be radiated fast by the inorganic filler. This provides a reliable electronic component-equipped module 1. Moreover, selection of the inorganic filler makes it possible to vary the heat conductivity, coefficient of linear expansion, dielectric constant, withstand voltage, and the like of the electric insulating board 2 according to the built-in electronic components. Furthermore, when the electronic component-equipped module 1 includes a semiconductor element and a chip capacitor, noise in electric signals can be reduced by reducing the distance between the semiconductor element and the chip capacitor.

The thermosetting resin contained in the mixture preferably contains at least one thermosetting resin selected from an epoxy resin, a phenol resin, and a cyanate resin. This is because these resins are excellent in heat resistance and electric insulating property.

In the electronic component-equipped module 1, the inorganic filler preferably contains at least one inorganic filler selected from Al₂O₃, MgO, BN, AlN, and SiO₂ as shown in (Table 1). The use of these inorganic fillers provides an electric insulating board 2 with an excellent radiating property. The use of MgO as an inorganic filler enables an increase in the coefficient of linear expansion of the electric insulating board. The use of SiO₂ (particularly amorphous SiO₂) as an inorganic filler enables a reduction in the dielectric constant of the electric insulating board 2. The use of BN as an inorganic filler enables a reduction in the coefficient of linear expansion of the electric insulating board.

The amount of inorganic filler mixed is preferably 70 to 95 wt %. Less than 70 wt % of inorganic filler makes it difficult to provide a desired thickness because the mixture flows excessively when the mixture is pressurized. More than 95 wt % of inorganic filler substantially prevents the mixture from flowing, resulting in a void between the buried electronic component and the mixture.

The conductive resin composition preferably contains, as a conductive component, metal grains containing one metal selected from gold, silver, copper, and nickel, and as a resin component, an epoxy resin. This is because the metals listed above offer a low electric resistance and the epoxy resin has a high heat resistance and an excellent electric insulating property.

Description will be given of a method of manufacturing the plate-like member 20 (see FIG. 2(A)) and an example of a process of forming a plate-like member according to the present invention.

To produce the plate-like member 20, first, a predetermined amount of pasty mixture having the composition shown in (Table 1) is dropped onto a releasing film. The pasty mixture was produced by mixing the inorganic filler and the liquid thermosetting resin for about 10 minutes using a stirring mixer. The stirring mixer used loads the inorganic filler and the liquid thermosetting resin into a vessel of a predetermined capacity and rotates and revolves the vessel. A sufficiently dispersed condition is obtained even with the relatively high viscosity of the mixture. Furthermore, a polyethylene terephthalate film of thickness 75 μm is used as the releasing film. Surfaces of the film are subjected to a releasing treatment with silicon.

Then, a releasing film is further laid on top of the pasty mixture dropped onto the releasing film. The structure is then pressed with a pressurizing press so that the resulting structure has a thickness of 500 μm. The plate-like member 20 is thus obtained.

Then, the plate-like member 20, sandwiched between the releasing films, is heated for each releasing film and thermally treated under conditions in which the plate-like member 20 loses the viscosity thereof. In the heat treatment, the plate-like member is held at 120° C. for 15 minutes. The thermal treatment loses the viscosity of the plate-like member 20 to allow the releasing films to be easily peeled off. The liquid epoxy resin used in the present embodiment has a curing temperature of 130° C. and is thus uncured (this condition is hereinafter referred to as a B stage) under the thermal treatment conditions. Thus, by thermally treating the plate-like member 20 at temperatures lower than the curing temperature of the thermosetting resin, it is possible to eliminate the viscosity while maintaining the flexibility of the mixture. This facilitates the subsequent process. Furthermore, when the thermosetting resin in the mixture is dissolved by a solvent, the thermal treatment enables the solvent to be partly removed.

Now, description will be given of evaluation of the performance of the plate-like member 20 obtained as described above.

The releasing films are peeled off the plate-like member 20. Then, the plate-like member 20 is sandwiched between heat-resistant releasing films (PPS: polyphenylene sulfite; thickness: 75 μm) and heated at 170° C. while being pressurized at 50 kg/cm². The plate-like member 20 is thus cured.

Then, the heat-resistant releasing films are peeled off the cured plate-like member 20 to obtain the electric insulating board 2 (see FIG. 1).

The electric insulating board 2 was processed to predetermined dimensions. The heart conductivity and coefficient of linear expansion, and the like of the electric insulating board 2 were then measured. For the heat conductivity, the material was cut into samples of 10 mm squares, and a surface of each of the samples was brought into contact with a heater to be heated. The heat conductivity was then mathematically determined on the basis of a rise in the temperature of a surface of the sample which was opposite the surface contacted with the heater. For the coefficient of linear expansion, measurements were made of variations in the dimensions of the electric insulating board 2 observed when the temperature was raised from the room temperature to 140° C. The variations were then averaged to determine the coefficient of linear expansion. For the withstand voltage, an AC voltage was supplied to the electric insulating board 2 in a thickness direction thereof to determine the withstand voltage. The withstand voltage per unit thickness was then calculated.

As shown in (Table 1), the electric insulating board 2 produced as described above exhibited a heat conductivity about 10 times as high as that of a conventional glass-epoxy board (heat conductivity: 0.2 w/mK to 0.3 w/mK) when Al₂O₃ was used as an inorganic filler. When the amount of Al₂O₃ was at least 85 wt %, the heat conductivity was at least 2.8 w/mK. Additionally, Al₂O₃ is advantageously inexpensive.

Now, with reference to FIGS. 2(A) to 2(F), description will be given of a method of manufacturing the electronic component-equipped module using the plate-like member 20.

As shown in FIG. 2(B), through-holes 21 are formed at desired positions on the plate-like member 20. The through-holes 21 can be formed by, for example, laser processing, drilling, or processing with a mold. The laser processing is preferred since it enables the through-holes 21 to be formed at very small pitches and prevent possible shavings. The laser processing can be easily achieved using carbon dioxide gas laser or excimer laser.

The through-holes 21 may be formed simultaneously with the formation of the plate-like member 20 based on molding of the pasty mixture. This step corresponds to an example of a through-hole forming process according to the present invention.

Subsequently, as shown in FIG. 2(C), a conductive resin composition 22 is filled into the through-hole 21. This step corresponds to an example of a filling process according to the present invention.

In parallel with the steps shown in FIGS. 2(A) to 2(C), as shown in FIG. 2(D), the electronic components 12 and 13 are mounted on a surface 30 of the first board 3. The electronic components 14 and 15 are mounted on a surface 31 of the first board 3. The surface 30 is to be located opposite and in contact with the plate-like member 20.

Of course, instead of passive components such as a capacitor and a resistor, the electronic components 12, 13, 14, and 15 may be semiconductor packages or bare semiconductor chips.

This step corresponds to an example of a mounting process according to the present invention. Furthermore, an example of one surface of the first board according to the present invention corresponds to the surface 31 according to the present embodiment. An example of the other surface of the first board according to the present invention corresponds to the surface 30 according to the present embodiment. In parallel with the steps in FIGS. 2(A) to 2(C), as shown in FIG. 2(F), the second board 4 is prepared.

Then, the first board 3 and the second board 4 are inspected for functions. Here, the first board 3 and the second board 4 are not connected together but the electronic components have been mounted on the first board 3. Thus, the first board 3 and the second board 4 are jointed together via a connector or a jig to form a circuit, which is then inspected.

Description will be given of an example of a step of inspecting the boards using an inspection jig by way of example.

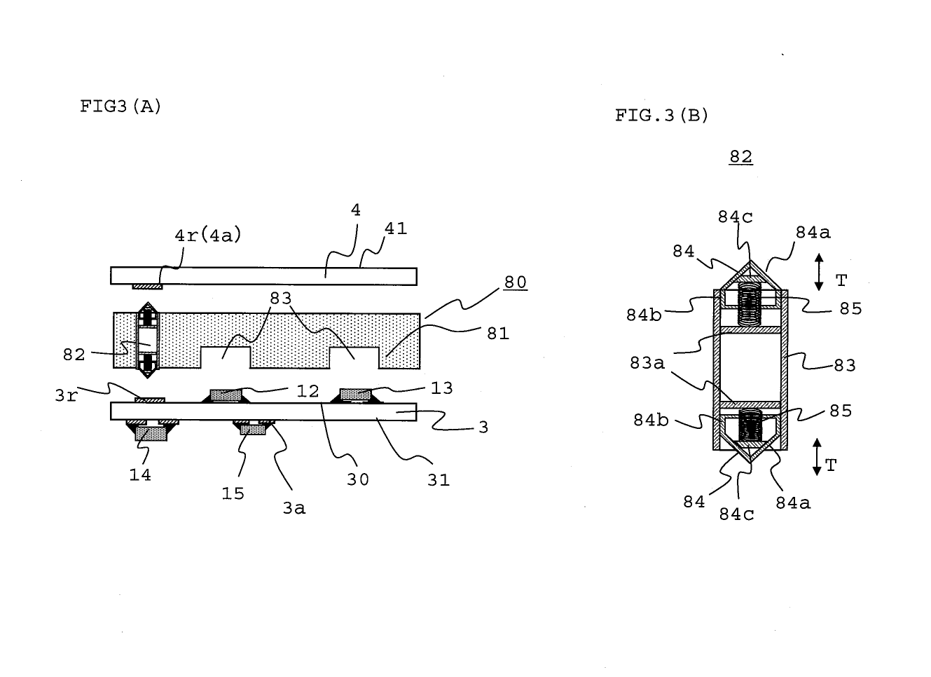

FIG. 3(A) is a sectional view illustrating a method of inspection using an inspection jig. As shown in FIG. 3(A), an inspection jig 80 is placed between the first board 3 with the electronic components 12, 13, 14, and 15 mounted thereon as shown in FIG. 2(D) and the second board 4. The inspection jig 80 has a plate-like member 81 such as resin which is penetrated by a pin 82 in a vertical direction. Voids 83 are formed in parts of the inspection jig 80 which are opposite the electronic components 12 and 13.

The pin 82 electrically connects an electrode portion of the wiring pattern 3a on the first board 3 to an electrode portion of the wiring pattern 4a on the second board 4; the wiring patterns 3a and 4a are connected together by the inner via 5 shown in FIG. 1. The pin 82 is formed of a conductive material such as metal. The electrode portions of the wiring patterns 3a and 4a (see FIG. 1) are shown as the electrode portions 3r and 4r in FIG. 3(A).

FIG. 3(B) is a schematic sectional view illustrating the structure of the pin 82. As shown in FIG. 3(B), the pin 82 is composed of a cylindrical member 83 and connection ends 84 provided at the top and bottom, respectively, of the cylindrical member 83. Each of the connection ends 84 has a cylindrical portion 84b and a conical portion 84a positioned at the tip of the cylindrical portion 84b. A support plate 84c is provided inside the conical portion 84a. One end of a spring member 85 is attached to the support plate 84c. The other end of the spring member 85 is attached to a support plate 83a provided inside the cylindrical member 83. The support plates 84c and 83a are arranged such that surfaces of the support plates 84c and 83a are perpendicular to a central axis of the cylindrical member 83 and conical portion 84b. This configuration allows each of the connection ends 84 to swing up and down with respect to the cylindrical member 83 as shown by arrow T in FIG. 3(B).

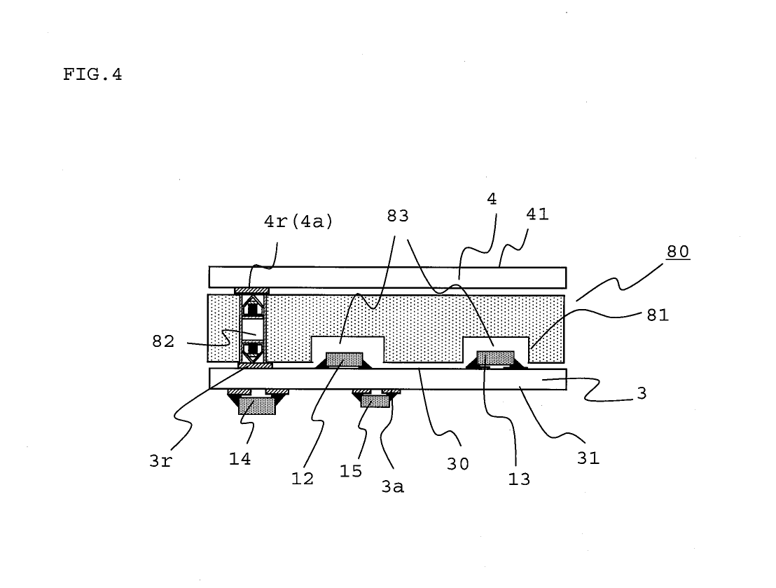

In the condition shown in FIG. 3(A), the inspection jig 80 and the second board 4 are placed on the first board 3 as shown in FIG. 4. At this time, the electronic components 12 and 13 are inserted into the voids 83. The electrode portions 3r and 4r of the wiring patterns 3a and 4a are arranged over and under the pin 82. When the first board 3, the inspection jig 80, and the second board 4 are arranged as described above, the elastic force of the spring member 85 contacts the upper and lower connection ends 84 with the electrode portions 3r and 4r. Thus, the first board 3 and the second board 4 are electrically connected together by the pin 82.

In this condition, the circuit is energized as is the case with the actual use to inspect whether or not the first board 3 and the second board 4 provide predetermined functions.

After the inspection, repairs or the like are performed as required.

The first board 3 and the second board 4 may be separately inspected. This step corresponds to an example of an inspecting process according to the present invention. However, the boards may be inspected after the formation of the resin layer 16, described below.

Then, as shown in FIG. 2(E), resin is applied to the surface 31 of the first board 3 so as to bury or cover the electronic components 14 and 15 for flattening. Since the electronic component 14 is higher than the electronic component 15, the resin layer 16 is formed to be as high as the electronic component 14. Consequently, the electronic component 15 is completely covered with the resin.

Alternatively, the resin layer 16 may be formed by applying a liquid resin by dispensation or using a film-like resin. The applied resin may be completely cured or cured to the degree that the components mounted in the step shown in FIG. 2(G) are not affected. Furthermore, the resin may contain a filler such as SiO₂.

The resin layer 16 corresponds to an example of an abutting portion according to the present invention. The step of applying the resin corresponds to an example of a process of forming an abutting portion according to the present invention.

Subsequently, as shown in FIG. 2(F), the first board 3 with the electronic components 12, 13, 14, and 15 mounted thereon, the plate-like member 20 shown in FIG. 2(C) and the second board 4 are aligningly stacked.

The aligningly stacking step corresponds to an example of a process of aligningly stacking the first board, the plate-like member and the second board according to the present invention. A top surface 20x of the plate-like member 20 shown in FIG. 2(G) corresponds to an example of the other surface of the plate-like member according to the present invention. A bottom surface 20y of the plate-like member 20 corresponds to an example of one surface of the plate-like member according to the present invention.

Subsequently, as shown in FIG. 2(G), the aligningly stacked boards and plate-like member are pressurized to form a plate-like member with the electronic components 12 and 13 buried therein (see arrow S in FIG. 2(G)) . This step corresponds to an example of a pressurizing process according to the present invention.

The pressurized stack is heated to cure the thermosetting resin in the plate-like member 20 and conductive resin composition 22 to form the electric insulating board 2 with the electronic components 12 and 13 buried therein. This step corresponds to an example of a heating process according to the present invention.

The stack is heated at a temperature equal to or higher than that at which the thermosetting resin in the plate-like member 20 and the conductive resin composition 22 is cured (for example, 150° C. to 260° C.) The plate-like member 20 becomes the electric insulating board 2, and the conductive resin composition 22 becomes the inner via 5 (see FIG. 2(H)).

This step allows the first board 3, the second board 4, the electronic components 12 and 13, and the electric insulating board 2 are mechanically firmly bonded together. Furthermore, the inner via 5 electrically connects the first board 3 and the second board 4 together. Thus, the through-hole 21 is formed in the plate-like member 20, with the thermosetting conductive resin composition 22 filled in the through-hole 21. Therefore, in the heating step, the conductive resin composition is cured to allow the first board 3 and the second board 4 to be easily joined electrically together.

The pressurizing step and the heating step may be separately carried out. However, in curing the thermosetting resin in the plate-like member 20 and conductive resin composition 22, the mechanical strength of the electronic component-equipped module can be improved by pressurizing the stack being heated, at a pressure of 10 kg/cm² to 200 kg/cm² (simultaneously performing the heating and the pressurization) (this also applies to embodiments described below).

As described above, Embodiment 1 flattens the surface 31 side with the electronic components mounted thereon to allow the pressurization to be easily performed using a pressurizing facility such as a press machine even after the electronic components have been mounted on both surfaces of the board. Thus, before the pressurization, the electronic components can be mounted on both surfaces of the board, which can then be inspected for functions. As a result, a possible defect in any electronic component or mounting can be easily found for repairs.

Furthermore, it is possible to determine before the pressurization that the first board 3 and the second board 4 are acceptable. Thus, if the electronic component-equipped module 1 becomes defective, the defect can be determined to be associated with the pressurizing or heating step and due to the plate-like member 20.

Additionally, in Embodiment 1, the first board 3 and the second board 4 are electrically connected together using the inner via 5. However, the first board 3 and the second board 4 are electrically connected together using means such as solder, through-hole plating, or bumps.

Embodiment 1 uses the conductive resin composition 22 as a conductive substance to be filled into the through-hole 21. However, any thermosetting conductive substance may be used (this also applies to the description below).

### Embodiment 2

Description will given be below of a method of manufacturing an electronic component-equipped module according to Embodiment 2 of the present invention. The method of manufacturing the electronic component-equipped module according to Embodiment 2 involves basically the same steps as those in Embodiment 1 except that a void is formed in the plate-like member and that a metal foil is located on the resin layer. Thus, these differences will be mainly described.

An electric insulating board 2 used in Embodiment 2 uses sample 13 in (Table 1) as a material. Sample 13 is composed of 85 wt % of SiO₂ (manufactured by KANTO CHEMICAL CO., INC.; spherical; average grain size: 5 μm), 14.5 wt % of liquid epoxy resin (manufactured by JAPAN REC CO., LTD.; EF-450), and 0.5 wt %.of coupling agent (manufactured by AJINOMOTO CO., INC. and containing titanate; 46B).

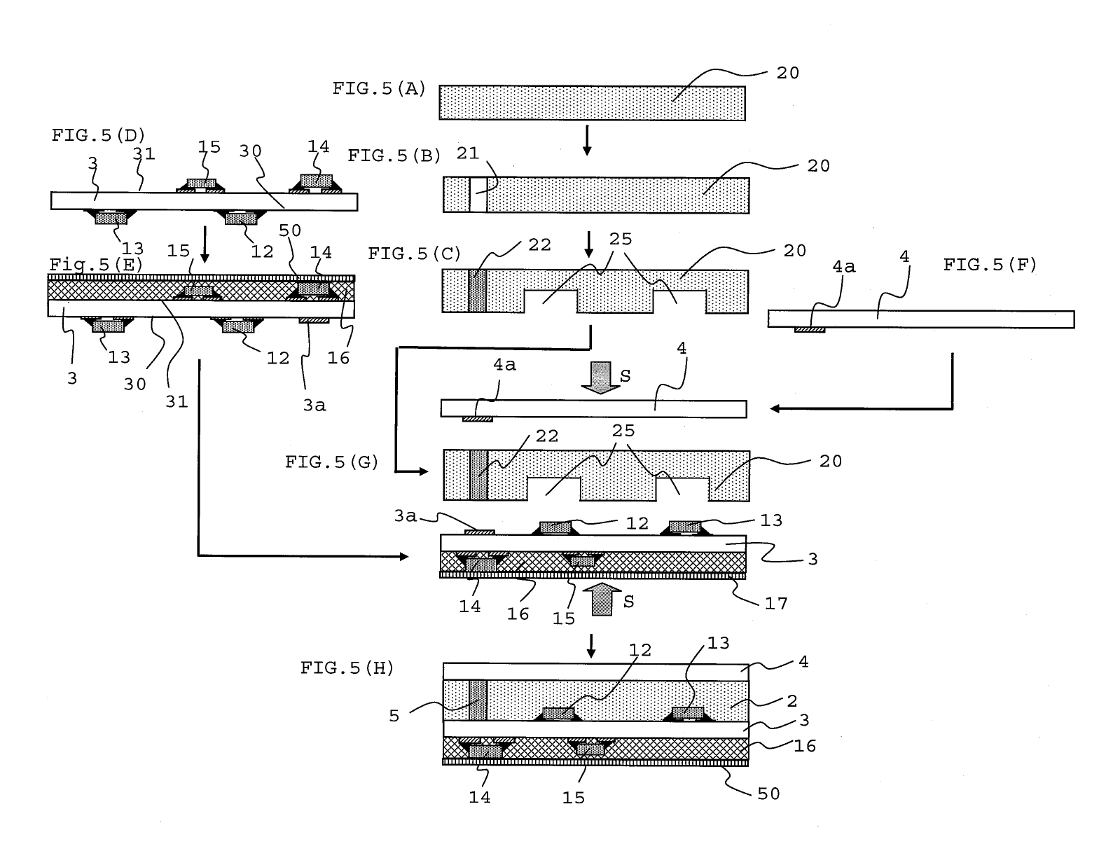

FIGS. 5(A) to 5(H) are sectional views showing a process of manufacturing a circuit component-equipped module according to Embodiment 2.

The above-described material was treated under conditions similar to those in Embodiment 1 to produce the plate-like member 20 (thickness: 500 μm) shown in FIG. 5(A). The plate-like member 20 was cut to a predetermined size. Carbon dioxide gas laser was used to form the through-hole 21 (diameter: 0.15 mm) for inner via hole connection (see FIG. 5(B)).

The conductive resin composition 22 was filled into the through-hole 21 by screen printing (see FIG. 5(C)). The conductive resin composition 22 was produced by kneading 85 wt % of spherical copper grains, 3 wt % of bisphenol A type epoxy resin (manufactured by YUKA SHELL EPOXY CO., LTD.; Epicoat 828), 9 wt % of glycidyl ester-containing epoxy resin (manufactured by TOHTO KASEI CO., LTD.;YD-171), and 3 wt % of amine adduct curing agent (manufactured by AJINOMOTO CO., INC.; MY-24).

Embodiment 2 is different from Embodiment 1 in that in the step shown in FIG. 5(B), voids 25 are pre-formed in the plate-like member 20 in conformity with the shapes of the electronic components 12 and 13, built in the plate-like member 20.

FIG. 5(C) is a sectional view showing that the voids 25 have been formed in the plate-like member 20. The plate-like member 20 is in the B stage condition, and the strength of the plate-like member is increased by softening and then hardening the plate-like member 20 in a heating step.

Small-sized electronic components are prevented from being destroyed by the softened and flowing plate-like member 20. However, if the electronic components have large sizes or the mixture of the plate-like member 20 flows only insignificantly, the insufficient flow of the mixture may cause the electronic components to be destroyed.

In Embodiment 2, the voids 25 in conformity with the shapes of the electronic components are pre-formed in the plate-like member 20. This avoids the above-described problems.

Furthermore, in FIG. 5(D), resin is applied to the surface 31 of the first board 3 with the electronic components 12, 13, 14, and 15 mounted thereon for flattening as is the case with Embodiment 1 as shown in FIG. 5(E).

Subsequently, a copper foil 50 as a metal foil is placed on the resin flattened as shown in FIG. 5(E). This step corresponds to an example of a process of placing a metal foil according to the present invention.

The provision of the metal foil makes it possible to prevent, during the pressurization and heating using the press machine or the like, the resin layer 16 from being stuck to a jig or the like which is used in the pressurizing and heating steps. Furthermore, the provision of the copper foil 50 allows heat to be easily radiated from the electronic component-equipped module 1. Moreover, electric shield effect can be exerted by electrically connecting the metal foil to a housing of electronics.

The metal foil preferably contains at least one metal selected from gold, silver, copper, nickel, and aluminum. This is because each of these metals can be easily processed into a foil and has a high heat conductivity.

Subsequently, as is the case with Embodiment 1, the first board 3, the plate-like member 20, and the second board 4 are aligned with one another as shown in FIG. 5(G) and pressurized and heated to form the electronic component-equipped module 1 as shown in FIG. 5(H).

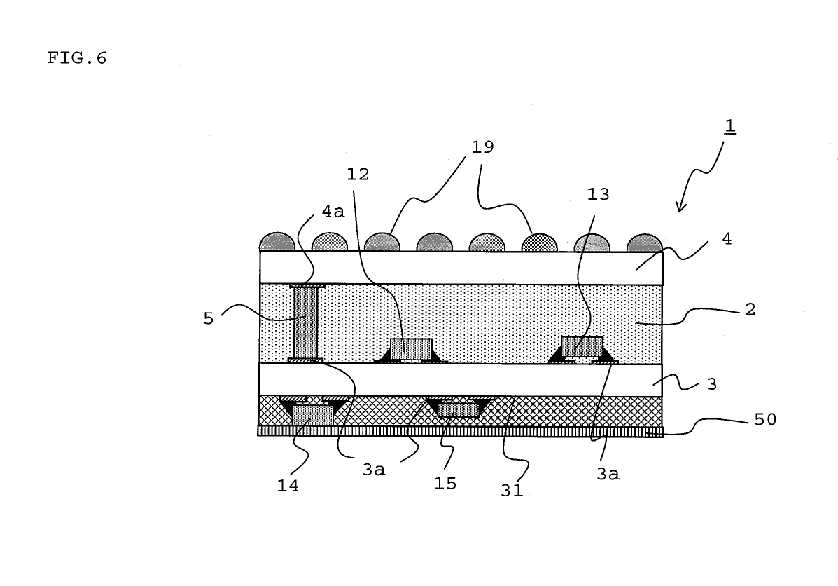

Finally, a form equivalent to a BGA (Ball Grid Array) type package can be produced by mounting solder balls 19 on the circuit component module manufactured as shown in FIG. 6. In FIG. 6, the wiring pattern on the surface of the second board 4 with the solder balls 19 mounted thereon is omitted.

In Embodiment 2, like Embodiment 1, flattening the surface 31 side allows pressurization to be performed after the electronic components have been mounted on the surface 31 side. Thus, before pressurization, the board can be inspected for functions with the electronic components mounted on both surfaces of the first board 3.

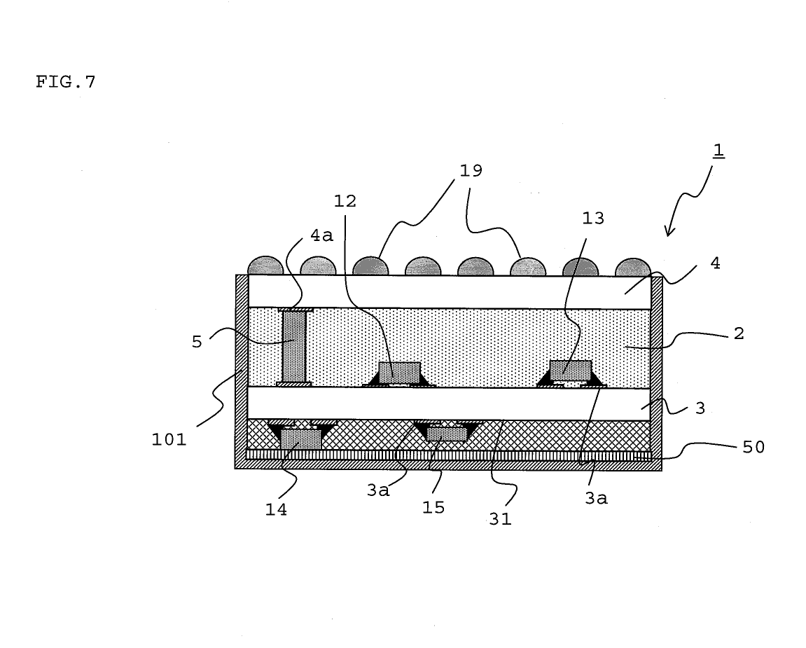

The electric shield effect can also be exerted by covering the entire electronic component-equipped module 1 with a plating film 101 except for the surface of the electronic component-equipped module 1 on which the solder balls 19 are arranged and electrically connecting the plating film 101 to ground inside the electronic component-equipped module 1 as shown in FIG. 7. In this case, the electronic component-equipped module 1 and the plating film 101 are electrically connected together by contacting the plating film 101 with ground patterns exposed from end surfaces of the first board 3 or second board 4 in the electronic component-equipped module 1.

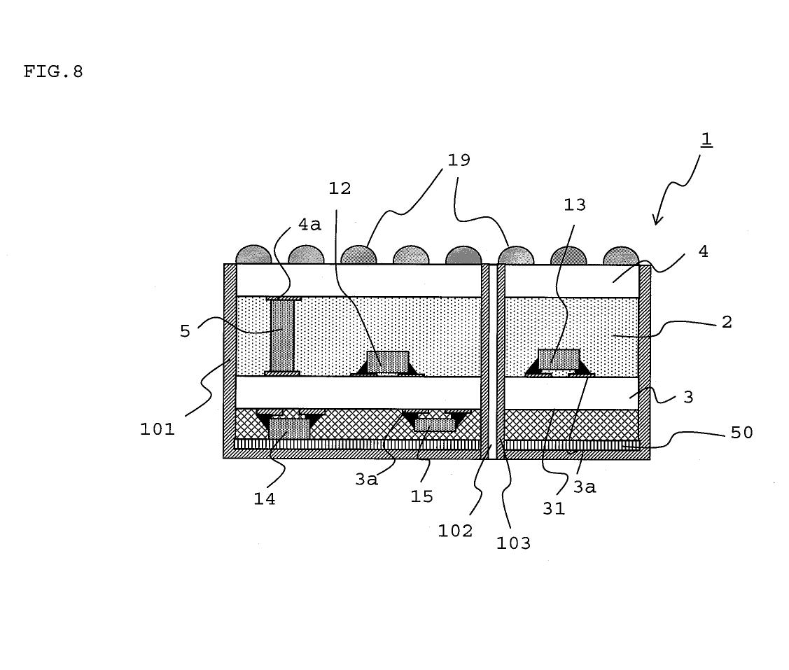

The ground inside the electronic component-equipped module 1 and the plating film 101 can be electrically connected together by forming the through-hole 102 in the electronic component-equipped module 1 by drilling or the like and simultaneously forming a plating film 103 inside the through-hole 102 as shown in FIG. 8.

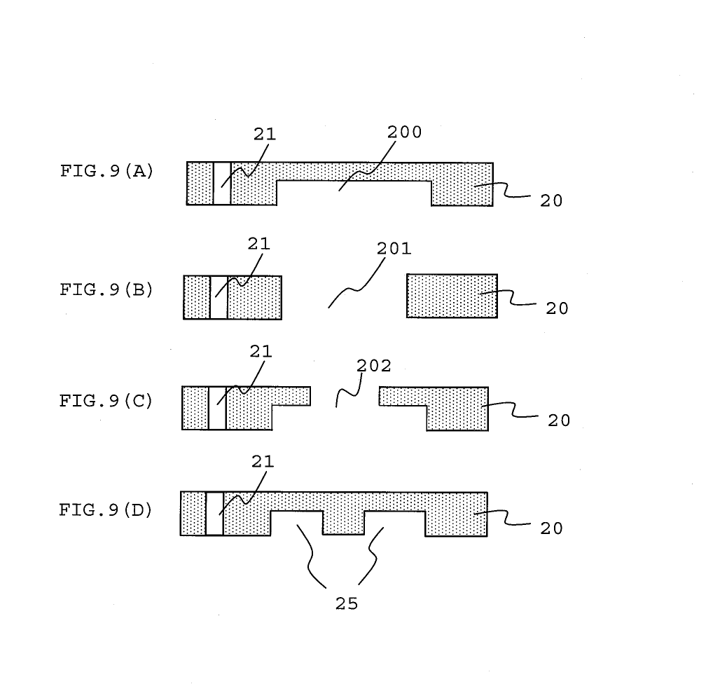

The shape of the voids 25, in which the electronic components 14 and 15 are arranged, is not limited to the shape of the voids 25 in Embodiment 2. The shape may be as shown in FIGS. 9(A) to 9(C). FIG. 9(D) shows the shape of the voids 25 formed in the plate-like member 20 in Embodiment 2.

In FIG. 9(A), unlike Embodiment 2, one void 200 is formed in the plate-like member 20. In FIG. 9(B), a void 201 is formed through the plate-like member 20. FIG. 9(C) shows a void 202 being the void 200 in FIG. 9(A) shaped so as to extend further upward to penetrate the plate-like member 20.

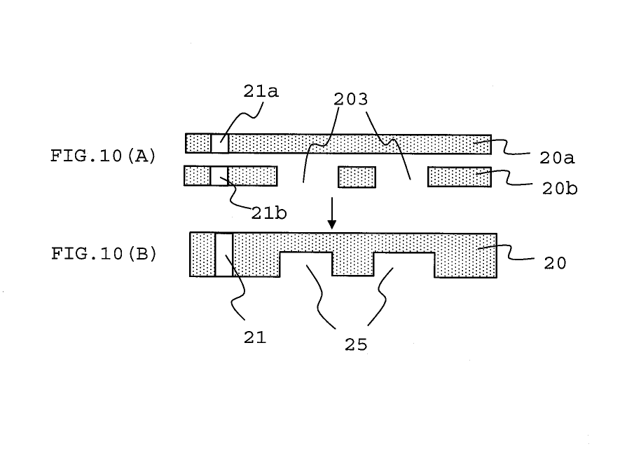

The voids 25 and the through-hole 21 may be made by joining together plate-like members 20a and 20b in which through-holes 21a and 21b are already formed as shown in FIGS. 10(A) and 10(B). In this case, penetrating portions 203 are formed in the plate-like member 20b so as to form the voids 25 when the plate-like members 20a and 20b are joined together. The through-holes 21a and 21b constitute the through-hole 21.

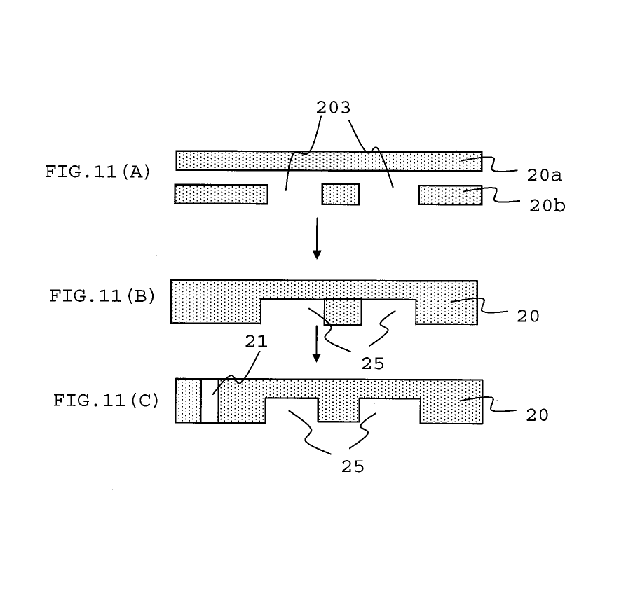

Furthermore, as shown in FIGS. 11(A) to 11(C), the through-hole 21 may be formed (see FIG. 11(C)) after the plate-like members 20a and 20b (see FIG. 11(A)) have been joined together (see FIG. 11(B)).

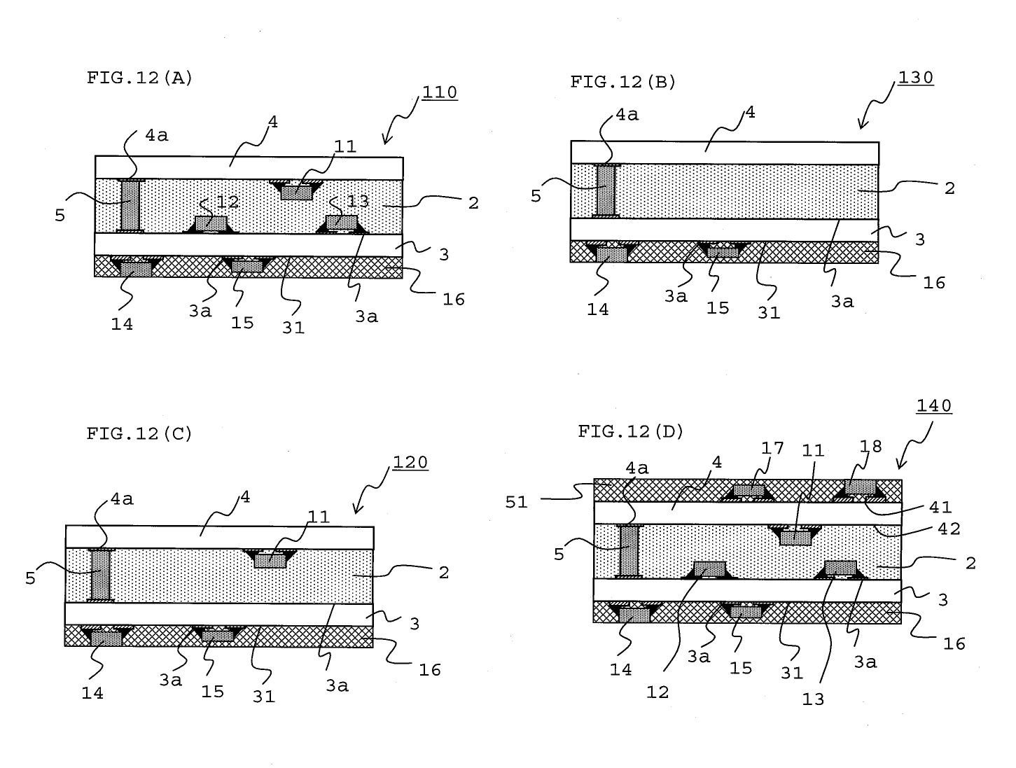

In Embodiments 1 and 2, described above, the electronic components are not mounted on the second board 4. However, the electronic component 11, built in the electric insulating board 2, may be mounted on the second board 4 as in the electronic component-equipped module 110 shown in FIG. 12(A).

In Embodiments 1 and 2, described above, the electronic components are mounted on both surfaces of the first board 3. However, the effects of the present invention can also be exerted by even an electronic component-equipped module 130 shown in FIG. 12(B) and in which the electronic components 12 and 13 are not mounted, with no electronic component built in the electric insulating board 2.

That is, the effects of the present invention can be exerted by any electronic component-equipped module having electronic components at least on a surface of the board which is pressed by the press machine.

That is, in the prior art, the electronic components cannot be arranged on the surface to be contacted with the press machine, before the pressurizing step. However, the formation of the resin layer 16 shown in FIG. 12(B) enables the pressurizing step to be carried out even after the electronic components have been mounted.

Thus, the boards can be individually inspected for functions before being pressurized to complete the module.

Alternatively, the configuration of an electronic component-equipped module 120 shown in FIG. 12(C) may be used in which the electronic components 12 and 13 are not mounted on the inner surface 30 of the first board 3 in the electronic component-equipped module 110 shown in FIG. 12(A).

Moreover, electronic components 17 and 18 may be mounted on an outer surface 41 of the second board 4 as is the case with an electronic component-equipped module 140 shown in FIG. 12(D). With this configuration, before pressurization, the electronic components 17 and 18 need to be mounted on the outer surface 41 of the second board 4, which is then inspected for functions. Thus, a resin layer 51 is also formed outside the second board 4.

An example of the other surface of the second board which is positioned opposite the plate-like member corresponds to the surface 41. An example of one surface of the second board according to the present invention corresponds to the surface 42 (see FIG. 2(G)).

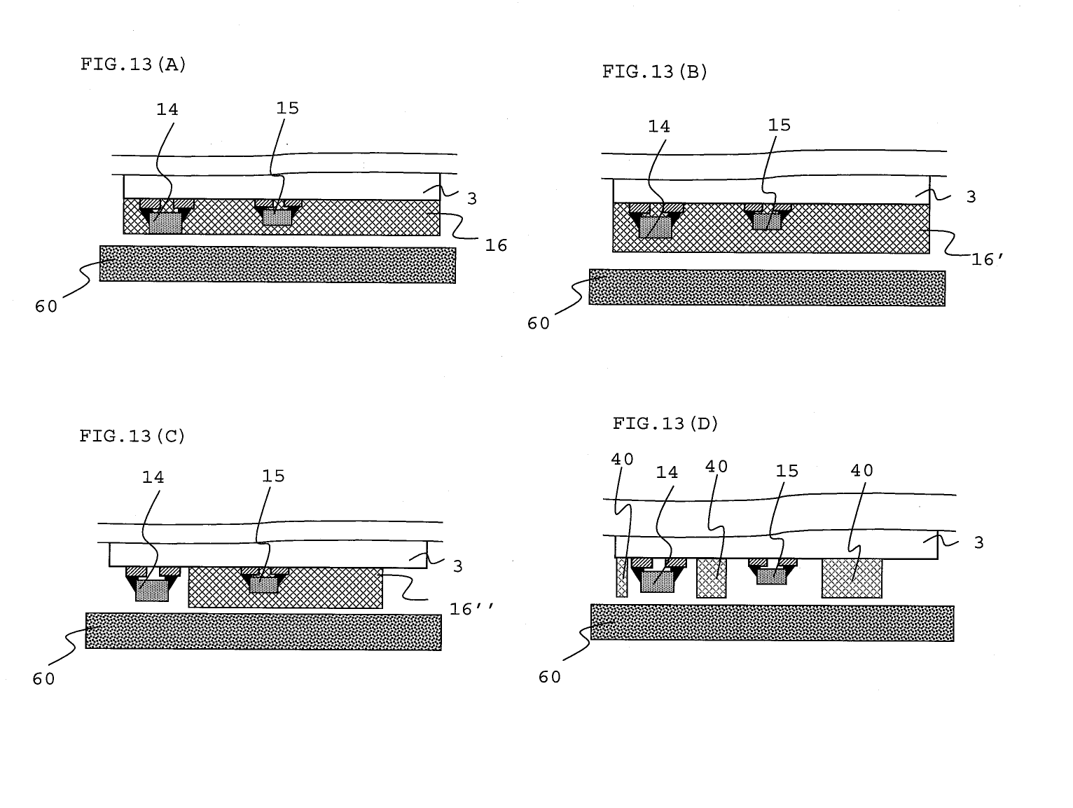

In Embodiments 1 and 2, as shown in a partially enlarged view of the electronic component-equipped module 1 in FIG. 13(A), the resin layer 16 on the outer surface 31 of the first board 3 is formed to be as high as the electronic component 14. However, the resin layer 16 may be formed higher than the electronic component 14 so as to cover the electronic component 14 as is the case with a resin layer 16′ shown in FIG. 13(B). FIG. 13(A) shows a press mold 60.

In Embodiments 1 and 2, described above, as shown in FIG. 13(A), the electronic components 14 and 15 on the outer surface 31 of the first board 3 are respectively buried and covered with resin to flatten the surface 31 side, and the flattened surface is pressed by the press mold 60. In FIG. 13(A), the resin is applied all over the surface 31 except for the areas thereof in which the electronic components 14 and 15 are formed, to form the resin layer 16. However, as shown in FIG. 13(C), not the entire surface 31 needs be applied with the resin as in the case of a resin layer 16″.

The resin layer 16″ corresponds to an example of an abutting portion formed on a part of the surface according to the present invention. The resin layer 16″ is formed to have a uniform height so as to be parallel with the surface 31. The height of the resin layer 16″ is equal to or greater than that of the electronic component 14. Furthermore, the resin layer 16″ has an appropriate size of area that allows the press mold 60 to stably pressurize the resin layer 16″.

Furthermore, as shown in FIG. 13(D), the resin may be applied on any of those areas of the surface 31 in which the electronic components 14 and 15 are not formed, to form a plurality of abutting parts 40 abutting against the press mold 60. The plurality of abutting parts 40 also correspond to an example of the abutting portion formed on a part of the surface according to the present invention. The plurality of abutting parts 40 have an equal height that is equal to or greater than that of the highest electronic component 14 on the surface 31.

By forming, on the surface 31, the plurality of abutting parts 40 corresponding to the appropriate size of area that allows the press mold 60 to perform stable pressurization, it is possible to achieve the pressurization using the press mold 60 as is the case in which flattening is performed.

This step corresponds to an example of a process of forming an abutting portion according to the present invention.

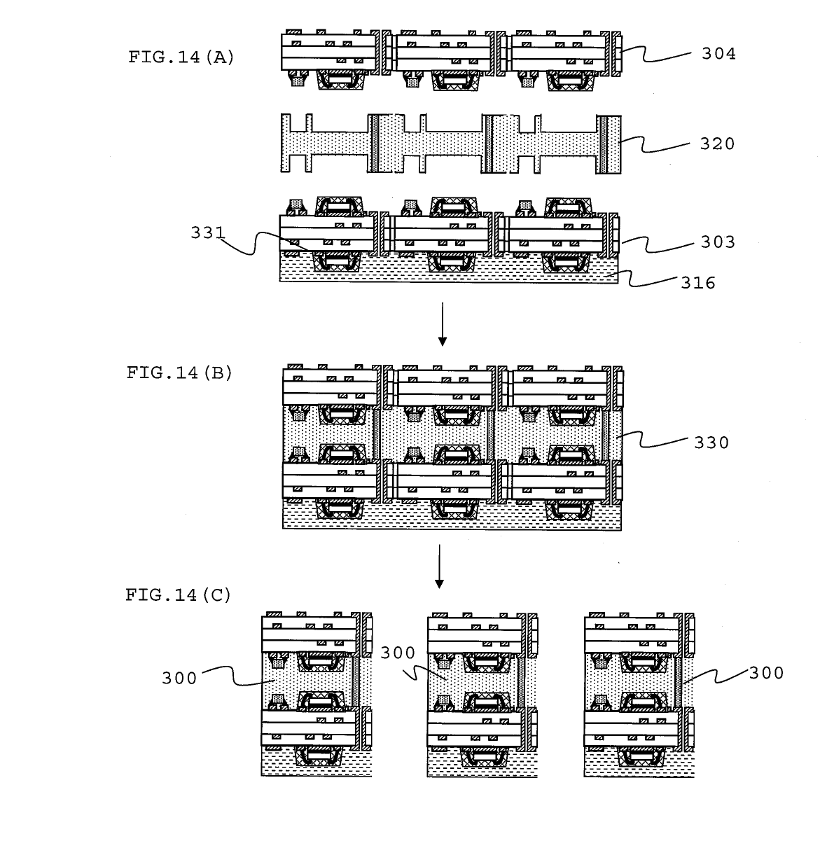

In Embodiments 1 and 2, described above, the electronic component-equipped modules 1 are individually manufactured. However, as shown in FIGS. 14(A). to 14(C), a large number of electronic component-equipped modules 300 are produced at a time as a mass of electronic component-equipped modules, which is then divided into individual modules. FIG. 14(A) shows that a first board 303, a second board 304, and a plate-like member 320 are aligned with one another in order to form three electronic component-equipped modules 300. A resin layer 316 is formed on an outer surface 331 of the first board 303. In this condition, the boards and the plate-like member are pressurized and heated to obtain a stack 330 having the first board 303, the second board 304, and the plate-like member 320 joined together as shown in FIG. 14(B).

Then, the stack 330 is cut into the individual electronic component-equipped modules 300. The electronic component-equipped modules 300 shown in FIG. 14(C) are thus obtained.

In Embodiments 1 and 2, two electronic components are mounted on each surface of the first board 3. However, the number of electronic components can be appropriately varied.

The above-described electronic component modules or electronic component-equipped modules are preferably used in electronics. In particular, the electronic component modules or electronic component-equipped modules are preferably used in portable electronics (for example, cellular phones and PDAS) that undergo strict limitations on mounting area. However, the electronic component modules or electronic component-equipped modules are also used in electronics such as what is called digital electric appliances (including digital televisions).

The present invention provides the electronic component module which is effective for allowing the boards to be precisely inspected before pressurization and which is thus useful as an electronic component-equipped module or the like, and also provides the method of manufacturing the electronic component-equipped module.

What is claimed is:

1. A method of manufacturing an electronic component module, the method comprising:
forming a plate-like member containing an uncured thermosetting resin;
mounting one or more electronic components on at least one surface of a first board;
forming an abutting portion burying or covering the electronic components on the one surface of the first board to flatten the one surface side;
inspecting the first board after (a) the mounting one or more electronic components on at least one surface of a first board or (b) the forming an abutting portion burying or covering the electronic components on the one surface of the first board to flatten the one surface side;
aligningly stacking the first board, the plate-like member, and a second board so that the other surface of the first board on which the abutting portion is not formed is opposite one surface of the plate-like member and so that the other surface of the plate-like member is opposite one surface of the second board;
pressurizing the first board, the plate-like member, and the second board which have been stacked; and
heating the first board, the plate-like member, and the second board which have been stacked.

2. The method of manufacturing the electronic component module according to claim 1, wherein the mounting one or more electronic components on at least one surface of a first board means mounting an electronic component on the other surface as well as the one surface of the first board.

3. The method of manufacturing the electronic component module according to claim 1, further comprising:
forming a through-hole in the plate-like member; and
filling a thermosetting conductive material into the through-hole.

4. The method of manufacturing the electronic component module according to claim 1, wherein the mounting one or more electronic components on at least one surface of a first board means mounting one or more electronic components on at least the other surface of the second board, the other surface of the second board being positioned opposite the plate-like member, and
the forming an abutting portion burying or covering the electronic components on the one surface of the first board to flatten the one surface side means forming an abutting portion burying or covering the electronic components on the one surface of the second board to perform flattening.

5. The method of manufacturing the electronic component module according to claim 1, wherein the mounting one or more electronic components on at least one surface of a first board means also mounting one or more electronic components on the one surface of the second board which is opposite the other surface of the plate-like member.

6. The method of manufacturing the electronic component module according to claim 1, wherein the forming an abutting portion burying or covering the electronic components on the one surface of the first board to flatten the one surface side means forming the abutting portion by coating resin on the surface.

7. The method of manufacturing the electronic component module according to claim 1, further comprising;
placing a metal foil on the flattened surface.

8. A method of manufacturing an electronic component module, the method comprising:
forming a plate-like member containing an uncured thermosetting resin;
mounting one or more electronic components on at least one surface of a first board;
forming an abutting portion on a part of the one surface of the first board in which the electronic components are not formed, the abutting portion having a height that is uniform and equal to or greater than that of a highest one of the electronic components on the one surface of the first board;
inspecting the first board after (a) the mounting one or more electronic components on at least one surface of a first board or (b) the forming an abutting portion on a part of the one surface of the first board in which the electronic components are not formed, the abutting portion having a height that is uniform and equal to or greater than that of a highest one of the electronic components on the one surface of the first board;
aligningly stacking the first board, the plate-like member, and a second board so that the other surface of the first board on which the abutting portion is not formed is opposite one surface of the plate-like member and so that the other surface of the plate-like member is opposite one surface of the second board;
pressurizing the first board, the plate-like member, and the second board which have been stacked; and
heating the first board, the plate-like member, and the second board which have been stacked.

9. The method of manufacturing the electronic component module according to claim 8, wherein the mounting one or more electronic components on at least one surface of a first board means mounting an electronic component on the other surface as well as the one surface of the first board.

10. The method of manufacturing the electronic component module according to claim 8, further comprising:
forming a through-hole in the plate-like member; and
filling a thermosetting conductive material into the through-hole.

11. The method of manufacturing the electronic component module according to claim 8, wherein the forming an abutting portion on a part of the one surface of the first board in which the electronic components are not formed, the abutting portion having a height that is uniform and equal to or greater than that of a highest one of the electronic components on the one surface of the first board means forming the abutting portion by coating resin on the surface.

12. The method of manufacturing the electronic component module according to claim 8, wherein the abutting portion has a plurality of abutting parts, and
forming the abutting portion on the part of the surface in which the electronic components are not formed means forming a plurality of the abutting parts of the same height on the surface around peripheries of the electronic components.

13. An electronic component module comprising:
a plate-like member;
a first board provided on one surface of the plate-like member and having a surface located opposite the plate-like member at least on which one or more electronic components are mouneted;
a second board provided on a surface of the plate-like member, the surface of the plate-like member being positioned opposite the first board; and
an abutting portion burying or covering the electronic components on the surface of the first board to flatten the surface side.

14. An electronic component module comprising:
a plate-like member;
a first board provided on one surface of the plate-like member and having a surface located opposite the plate-like member at least on which one or more electronic components are mounted;
a second board provided on a surface of the plate-like member, the surface of the plate-like member being positioned opposite the first board; and
an abutting portion formed on a part of the surface of the first board in which the electronic components are not formed, the abutting portion having a height that is uniform and equal to or greater than that of a highest one of the electronic components on the surface of the first board.
